(19) United States
(12) Patent Application Publication
(10) Pub. No.: US 2023/0170427 A1
(43) Pub. Date: Jun. 1, 2023

(54) FOCAL PLANE ARRAY HAVING AN INDIUM ARSENIDE ABSORBER LAYER

(71) Applicant: CORNING INCORPORATED, Corning, NY (US)

(72) Inventors: Robert Gerald Benson, Keene, NH (US); Jeffry John Santman, Keene, NH (US)

(21) Appl. No.: 17/993,579

(22) Filed: Nov. 23, 2022

Related U.S. Application Data
(60) Provisional application No. 63/284,285, filed on Nov. 30, 2021.
(60) Provisional application No. 63/314,656, filed on Feb. 28, 2022.

(51) Int. Cl. H01L 31/0304; H01L 31/109; H01L 31/0352

(52) U.S. Cl. CPC H01L 31/0304; H01L 31/109; H01L 31/035236

(57) ABSTRACT

The present invention relates to a focal plane array having a substrate wafer; an n-type indium arsenide layer disposed atop the substrate wafer; a barrier layer disposed atop the substrate wafer; and a doped n-type layer disposed atop the barrier layer. The present invention further relates to a focal plane array, having a substrate wafer; an n-type indium arsenide layer disposed atop the substrate wafer; and a p-type indium arsenide layer positioned at a first surface of the n-type indium arsenide layer opposite an interface surface of the n-type indium arsenide and the substrate wafer.

### CROSS REFERENCE TO RELATED APPLICATION

This application claims the benefit of priority under 35 U.S.C. § 119 of U.S. Provisional Application Serial No. 63/284,285 filed on Nov. 30, 2021 and U.S. Provisional Application Serial No. 63/314,656 filed on Feb. 28, 2022, the content of which is relied upon and incorporated herein by reference in its entirety.

### FIELD

The present disclosure relates generally to focal plane arrays, and more particularly, to focal plane arrays having an indium arsenide absorber layer.

### BACKGROUND

Currently, in the hyperspectral imaging (HSI) area, only sensors based on the semiconducting material alloy Mercury Cadmium Tellerium, (HgCdTe or MCT) can simultaneously sense photons from the visible spectral band (i.e. about 400 nm) thru the Short Wave Infrared spectral band (i.e. about 2,500 nm) with sufficient quantum efficiency and dark current to be useful in HSI applications. The MCT arrays are based on elements from column II-VI of the periodic table and are very difficult and expensive to process. Only a small number of semiconducting foundries worldwide are capable of processing this material system. Also, the processing itself is extremely expensive and results in large cost burdens for those delivering HSI systems.

### SUMMARY

In a first embodiment, a focal plane array includes: a substrate wafer; an n-type indium arsenide layer disposed atop the substrate wafer; a barrier layer disposed atop the substrate wafer; and a doped n-type layer disposed atop the barrier layer.

A second embodiment of the present disclosure may include the first embodiment, wherein the substrate wafer is gallium antimony.

A third embodiment of the present disclosure may include the first embodiment, wherein the substrate wafer is indium arsenide.

A fourth embodiment of the present disclosure may include the first embodiment, wherein the substrate wafer is gallium arsenide.

A fifth embodiment of the present disclosure may include the first embodiment, wherein a thickness of the n-type indium arsenic layer is in the range of 2 microns to 8 microns.

A sixth embodiment of the present disclosure may include the first embodiment, wherein a metal layer is disposed atop the doped n-type layer.

A seventh embodiment of the present disclosure may include the first embodiment, wherein the n-type indium arsenic layer detects wavelengths in the range of 400 nm to 3 microns.

An eighth embodiment of the present disclosure may include the first embodiment, wherein the barrier layer is a Group III-V compound semiconducting material.

In a ninth embodiment, a focal plane array includes: a substrate wafer; an n-type indium arsenide layer disposed atop the substrate wafer; and a p-type indium arsenide layer positioned at a first surface of the n-type indium arsenide layer opposite an interface surface of the n-type indium arsenide and the substrate wafer.

A tenth embodiment of the present disclosure may include the ninth embodiment, wherein the substrate wafer is gallium antimony.

An eleventh embodiment of the present disclosure may include the ninth embodiment, wherein the substrate wafer is indium arsenide.

A twelfth embodiment of the present disclosure may include the ninth embodiment, wherein the substrate wafer is gallium arsenide.

A thirteenth embodiment of the present disclosure may include the ninth embodiment, wherein a thickness of the n-type indium arsenic layer is in the range of 2 microns to 8 microns.

A fourteenth embodiment of the present disclosure may include the ninth embodiment, wherein the n-type indium arsenic layer detects wavelengths in the range of 400 nm to 3 microns.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating the exemplary embodiments.

FIG. 1 depicts an exemplary focal plane array having an n-type indium arsenide absorber layer in accordance with embodiments of the current disclosure.

FIGS. 2A-2B depicts an alternative exemplary focal plane array having an n-type indium arsenide absorber layer in accordance with embodiments of the current disclosure.

### DETAILED DESCRIPTION

The present disclosure relates to focal plane arrays, and more particularly, to focal plane arrays having an indium arsenide absorber layer. The present disclosure uses a different material system, based on columns III-V of the period table, instead of the current MCT arrays based on elements from column II-VI of the periodic table which are very difficult and expensive to process. Advantageously, embodiments of the current disclosure can easily be processed at many foundries worldwide at low cost. Additionally, embodiments of the current disclosure will have similar quantum efficiency and dark current characteristics as the currently utilized MCT technology.

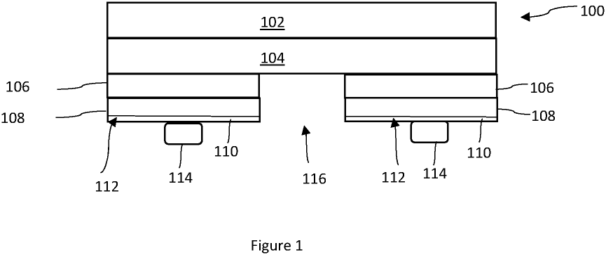

In one embodiment depicted in FIG. 1, the focal plane array 100 includes a substrate wafer 102. In embodiments, the substrate wafer 102 comprises gallium antimony. In embodiments, the substrate wafer 102 comprises indium arsenide. In embodiments, the substrate wafer 102 comprises gallium arsenide.

An n-type indium arsenide layer 104 is disposed atop the substrate wafer 102. The n-type indium arsenide layer 104 functions as an absorber layer within the focal plane array. In embodiments, the n-type indium arsenide layer 104 is disposed directly atop the substrate wafer 102. As used herein, a first material that is “disposed directly atop” a second material has no intervening layer disposed between the first material and the second material. In embodiments, the n-type indium arsenide layer 104 may be formed using known methods in the art including but not limited to chemical vapor deposition (CVD), plasma enhanced chemical vapor deposition (PECVD), and atomic layer deposition (ALD). In embodiments, the thickness of the n-type indium arsenide layer 104 is about 2 microns to about 8 microns. In embodiments, the thickness of the n-type indium arsenide layer 104 is about 3 microns to about 8 microns. In embodiments, the thickness of the n-type indium arsenide layer 104 is about 4 microns to about 8 microns. In embodiments, the thickness of the n-type indium arsenide layer 104 is about 5 microns to about 8 microns. In embodiments, the thickness of the n-type indium arsenide layer 104 is about 6 microns to about 8 microns. In embodiments, the thickness of the n-type indium arsenide layer 104 is about 7 microns to about 8 microns.

In embodiments, a barrier layer 106 is disposed atop the n-type indium arsenide layer 104. In embodiments, the barrier layer 106 is disposed directly atop the n-type indium arsenide layer 104. The barrier layer 106 functions to prevent current from flowing through the n-type indium arsenide layer 104 to the contacts (described below). In embodiments, the barrier layer 106 may be formed using known methods in the art including but not limited to chemical vapor deposition (CVD), plasma enhanced chemical vapor deposition (PECVD), and atomic layer deposition (ALD). In embodiments, the barrier layer 106 is a Group III-V compound semiconducting material, such as but not limited to aluminum antimonide (AlSb).

A doped n-type layer 108 is disposed atop the barrier layer 106. In embodiments, the doped n-type layer 108 is disposed directly atop the barrier layer 106. In embodiments, the doped n-type layer 108 may be formed using known methods in the art including but not limited to chemical vapor deposition (CVD), plasma enhanced chemical vapor deposition (PECVD), and atomic layer deposition (ALD). In embodiments, a metallization layer 110 (e.g. platinum and/or gold) is disposed on the surface 112 of the doped n-type layer 108. In embodiments, the metallization layer 110 may be formed using known methods in the art including but not limited to chemical vapor deposition (CVD), plasma enhanced chemical vapor deposition (PECVD), and atomic layer deposition (ALD). The metallization layer 110 contacts the metal contact 114 (e.g. indium).

In embodiments, a trench 116 is etched through the metallization layer 110, the doped n-type layer 108, and the barrier layer 106 to expose a surface of the n-type indium arsenide layer 104. The trench may be formed using known methods in the art, including but not limited to wet etching, selective etching, and plasma etching. After etching the trench 116, the metal contact 114 are electrically connected to a Read-Out Integrated Circuit (not shown).

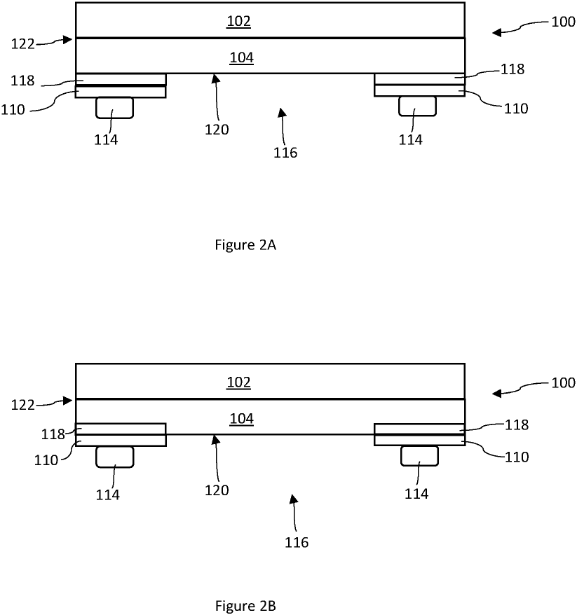

In an embodiment depicted in FIGS. 2A-2B, the focal plane array 100 includes a substrate wafer 102. In embodiments, the substrate wafer 102 comprises gallium antimony. In embodiments, the substrate wafer 102 comprises indium arsenide. In embodiments, the substrate wafer 102 comprises gallium arsenide. An n-type indium arsenide layer 104 is disposed atop the substrate wafer 102. The n-type indium arsenide layer 104 functions as an absorber layer within the focal plane array. In embodiments, the n-type indium arsenide layer 104 is disposed directly atop the substrate wafer 102. In the embodiment depicted in FIG. 2A, a p-type indium arsenide layer 118 is positioned at a first surface 120 of the n-type indium arsenide layer 104 opposite an interface surface 122 of the n-type indium arsenide and the substrate wafer 102. In embodiments, a metallization layer 110 (e.g. platinum and/or gold) is disposed on the p-type indium arsenide layer 118. The metallization layer 110 contacts the metal contact 114 (e.g. indium). In embodiments, a trench 116 is etched through the metallization layer 110, and the p-type indium arsenide layer 118 to expose a surface of the n-type indium arsenide layer 104. After etching the trench 116, the metal contact 114 are electrically connected to a Read-Out Integrated Circuit (not shown). In embodiments, the p-type indium arsenide layer 118 is implanted into the surface of the n-type indium arsenide layer 104. In embodiments, the p-type indium arsenide layer 118 is implanted to a depth of about at least 0.5 microns. In embodiments, the p-type indium arsenide layer 118 is implanted to a depth of about at least 1 micron. In embodiments, a metallization layer 110 (e.g. platinum and/or gold) is disposed on the implanted p-type indium arsenide layer 118. The metallization layer 110 contacts the metal contact 114 (e.g. indium). The metal contact 114 are electrically connected to a Read-Out Integrated Circuit (not shown).

While exemplary embodiments have been disclosed herein, it will be understood by those skilled in the art that various changes in form and details may be made therein without departing from the scope of the invention encompassed by the appended claims.

1. A focal plane array, comprising:
a substrate wafer;
an n-type indium arsenide layer disposed atop the substrate wafer;
a barrier layer disposed atop the substrate wafer; and
a doped n-type layer disposed atop the barrier layer.

2. The focal plane array of claim 1, wherein the substrate wafer is gallium antimony.

3. The focal plane array of claim 1, wherein the substrate wafer is indium arsenide.

4. The focal plane array of claim 1, wherein the substrate wafer is gallium arsenide.

5. The focal plane array of claim 1, wherein a thickness of the n-type indium arsenic layer is in the range of 2 microns to 8 microns.

6. The focal plane array of claim 1, wherein a metal layer is disposed atop the doped n-type layer.

7. The focal plane array of claim 1, wherein the n-type indium arsenic layer detects wavelengths in the range of 400 nm to 3 microns.

8. The focal plane array of claim 1, wherein the barrier layer is a Group III-V compound semiconducting material.

9. A focal plane array, comprising:
a substrate wafer;
an n-type indium arsenide layer disposed atop the substrate wafer; and
a p-type indium arsenide layer positioned at a first surface of the n-type indium arsenide layer opposite an interface surface of the n-type indium arsenide and the substrate wafer.

10. The focal plane array of claim 9, wherein the substrate wafer is gallium antimony.

11. The focal plane array of claim 9, wherein the substrate wafer is indium arsenide.

12. The focal plane array of claim 9, wherein the substrate wafer is gallium arsenide.

13. The focal plane array of claim 9, wherein a thickness of the n-type indium arsenic layer is in the range of 2 microns to 8 microns.

14. The focal plane array of claim 9, wherein the n-type indium arsenic layer detects wavelengths in the range of 400 nm to 3 microns.
